(19) United States
(12) Patent Application Publication
(10) Pub. No.: US 2005/0206364 A1
(43) Pub. Date: Sep. 22, 2005

(54) Apparatus and method for switch control, and voltage measuring device

(75) Inventors: Satoshi Ishikawa, Shizuoka (JP); Kohichi Yamamoto, Shizuoka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: YAZAKI CORPORATION

(21) Appl. No.: 11/069,972

(22) Filed: Mar. 3, 2005

(30) Foreign Application Priority Data
Mar. 22, 2004 (JP) 2004-082613

(51) Int. Cl. G01R 27/28

(52) U.S. Cl. 324/103 P

(57) ABSTRACT

A voltage-measuring device includes a capacitor for being connected sequentially to each of a plurality of unit cells connected in series to each other composing a battery pack. Further, the voltage-measuring device includes a plurality of switches for connecting sequentially the unit cells to the capacitor. The capacitor is charged by one of the unit cells, and reflects a voltage of the one of the unit cells. A logic circuit firstly turns one of two switches provided between the capacitor and a voltmeter, and then secondly turns the other switch on for connecting the voltmeter to the capacitor. The voltmeter measures a voltage across the capacitor when the other switch of the two switches is secondly turned on.

### BACKGROUND OF THE INVENTION

The priority application Number Japanese Patent Application 2004-082613 upon which this patent application is based is hereby incorporated by reference.

1. Field of the Invention

This invention relates to an apparatus and a method for controlling two switches respectively provided between terminals of a capacitor and terminals of a voltmeter for measuring a voltage across the capacitor, and relates to a voltage-measuring device having the apparatus for controlling the switches.

2. Description of the Related Art

As an applications for a voltage-measuring device for measuring a voltage across a capacitor, both of Japanese published unexamined patent applications No. Hei 11-248755 and No. 2002-156392 disclose a voltage-measuring device for measuring a voltage of a battery pack. This voltage-measuring device is mounted on a vehicle, and individually measures a voltage across each unit cell composing the battery pack via capacitors.

As shown in FIG. 1, the voltage-measuring device 11 includes a capacitor C1, and a plurality of switches S₁₁ to S₁₍ₙ₊₁₎ for connecting corresponding unit cells V₁ to Vₙ connected in series to each other, to the capacitor C1. In FIG. 1, each of the unit cells V₁ to Vₙ is a battery.

This voltage-measuring device 11 also includes a voltmeter 10 for measuring the capacitor C1, and switches S₂₁ and S₂₂ provided between the terminals of the capacitor C1 and terminals of the voltmeter 10. The voltmeter 10 is powered by a power source different from the battery pack P, and needs to be isolated from the battery pack P.

Voltage-measuring process is follows. By controlling the switches S₁₁ to S₁₍ₙ₊₁₎, the capacitor C1 is connected to the unit cells V₁ to Vₙ and charged sequentially. At each end of the charging time, all of the switches S₁₁ to S₁₍ₙ₊₁₎ are turned off to isolate the capacitor C1 from the battery pack P. Then the switches S₂₁ and S₂₂ are turned on, and the voltmeter 10 measures the voltage across the capacitor C1 reflecting the voltage across the corresponding unit cell.

According to the above, each of voltages across the unit cells V₁ to Vₙ can be individually measured via the capacitor C1, while the voltmeter 10 is isolated from the battery pack P.

As shown in FIG. 1, in this voltage-measuring device 11, stray capacitances Cs₁₁ to Cs_{1(N+1)} exist between the unit cells V₁ to Vₙ and a ground of the voltmeter 10. Similarly, stray capacitances Cs₂₁ to Cs_{2(N+1)} exist between the unit cells V₁ to Vₙ and one of two terminals of the capacitor C1, and Cs₃₁ to Cs_{3(N+1)} exist between the unit cells V₁ to Vₙ and the other terminal of the capacitor C1. Therefore, in the conventional voltage-measuring device 11, there is a problem described below.

This problem will be explained with reference to a timing chart in FIG. 5. Firstly, the capacitor C1 is charged by switching the switches S₁ₙ to S₁₍ₙ₊₁₎, and the voltage across the capacitor C1 becomes Vc reflecting a voltage across a unit cell Vm. Secondly, all the switches S₁₁ to S₁₍ₙ₊₁₎ are off, and then switches S₂₁ and S₂₂ are simultaneously on to connect the capacitor C1 to the voltmeter 10.

Because the potentials of the unit cells V₁ to Vₙ connected to the stray capacitors Cs₁₁ to Cs_{1(N+1)}, Cs₂₁ to Cs_{2(N+1)}, Cs₃₁ to Cs_{3(N+1)} are different from those of the terminals of the voltmeter 10, when the switches S₂₁ and S₂₂ are simultaneously turned on, currents flow through the stray capacitors Cs₁₁ to Cs_{1(N+1)}, Cs₂₁ to Cs_{2(N+1)}, Cs₃₁ to Cs_{3(N+1)}.

As the currents flow, as shown in FIG. 5, a switching noise is coupled to the voltage across the capacitor C1. Further, upon connecting to the voltmeter 10, the capacitor C1 is discharged gradually via an internal resistor of the voltmeter 10, so that the voltage across the capacitor C1 is reduced gradually.

Therefore, the problem is the conventional voltage-measuring device 11 having the voltmeter 10 cannot measure the voltage Vc accurately in this manner.

Accordingly, it is an object of this invention to provide an apparatus and a method for controlling two switches respectively provided between terminals of a capacitor and terminals of a voltmeter, and relates to a voltage-measuring device having the apparatus for controlling the switches for measuring accurately a voltage across each of unit cells composing a battery pack P.

### SUMMARY OF THE INVENTION

In order to attain the object, according to this invention, there is provided a switch control apparatus for checking voltages of a plurality of unit cells composing a battery pack, said switch control apparatus comprising:
a capacitor for being sequentially connected to the unit cells;
a voltmeter for measuring a voltage across the capacitor; and
two switches respectively provided between terminals of the capacitor and terminals of the voltmeter,
whereby either one of the two switches is firstly turned on, and then the other switch is secondly turned on.

According to another aspect of this invention, there is provided a switch control method for controlling two switches respectively provided between each of terminals of a capacitor sequentially connected to a plurality of unit cells composing a battery pack for checking voltages of the unit cells, and a voltmeter for measuring a voltage across the capacitor, said method comprising the steps of:
firstly turning either one of the two switches on; and
secondly turning the other switch on.

According to another aspect of this invention, there is provided a voltage-measuring device comprising:
a capacitor for being sequentially connected to a plurality of unit cells composing a battery pack;
a voltmeter for measuring a voltage across the capacitor;
two switches respectively provided between each of terminals of the capacitor and the voltmeter; and
a switch controller for controlling the two switches,
whereby any one of the two switches is firstly turned on, and then the other switch is secondly turned on,
whereby the voltmeter measures the voltage across the capacitor when the other switch is secondly turned on.

Preferably, the voltage-measuring device further comprising a filter being provided between the terminal of the capacitor connected to the switch to be firstly turned on and a ground of the voltmeter.

Preferably, the voltage-measuring device further comprising a filter being provided between the terminal of the voltmeter connected to the switch to be firstly turned on and a ground of the voltmeter.

The above and other objects, features, and advantages of this invention will be better understood when taken in connection with the accompanying drawings and description.

### BRIEF DESCRIPTION OF THE DRAWINGS

FIG. 1 is a schematic circuit diagram showing a first embodiment of a voltage-measuring device according to a switch control method of this invention;

FIG. 2 is a timing chart showing voltage changes with time across switches S₂₁, S₂₂ and the capacitor C1 of the voltage-measuring device in FIG. 1, according to the switch control method of this invention;

FIG. 3 is a schematic circuit diagram showing a second embodiment of the voltage-measuring device according to the switch control method of this invention;

FIG. 4 is a timing chart showing voltage changes with time across switches S₂₁, S₂₂ and the capacitor C1 of the voltage-measuring device in FIG. 3, according to the switch control method of this invention;

FIG. 5 is a timing chart showing voltage changes with time across switches S₂₁, S₂₂ and the capacitor C1 of the voltage-measuring device in FIG. 1, according to the conventional control method, and

FIG. 6 is a schematic circuit diagram showing another configuration of the second embodiment of the voltage-measuring device according to the switch control method of this invention.

### DESCRIPTION OF THE PREFERRED EMBODIMENTS

### First Embodiment

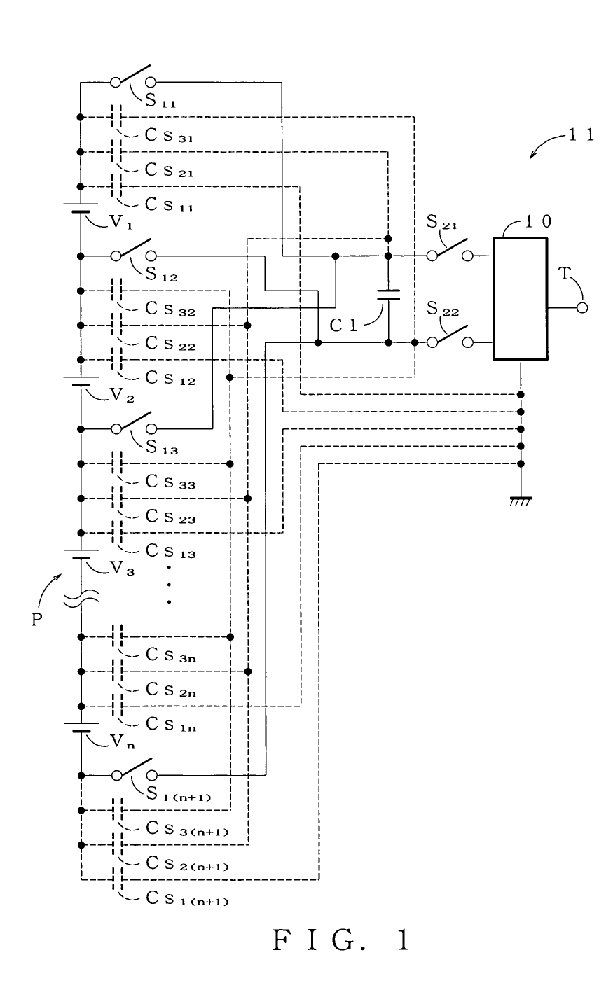

A first embodiment of a switch control apparatus, a witch control method, and a voltage-measuring device having the apparatus for controlling the switches will be explained with reference to Figures. A voltage-measuring device 11 in FIG. 1 includes a capacitor C1 for being connected to a battery pack P composed of a plurality of unit cells V₁ to Vₙ connected in series to each other.

Further, the voltage-measuring device 11 includes a plurality of switches S₁₁ to S₁₍ₙ₊₁₎ for connecting sequentially the unit cells V₁ to Vₙ to the capacitor C1. (n+1) of the switches S₁₁ to S₁₍ₙ₊₁₎ are provided for n of the unit cells V₁ to Vₙ on this voltage measuring circuit.

Both terminals of the capacitor C1 are connected to a voltmeter 10 with the switches S₂₁ and S₂₂. These switches S₁₁ to S₁₍ₙ₊₁₎, S₂₁ and S₂₂ are controlled by a not-shown logic circuit.

As shown in FIG. 1, in this voltage-measuring device 11, stray capacitances Cs₁₁ to Cs_{1(N+1)} exist between the unit cells V₁ to Vₙ and a ground of the voltmeter 10. Similarly, stray capacitances Cs₂₁ to Cs_{2(N+1)} exist between the unit cells V₁ to Vₙ and one of two terminals of the capacitor C1, and Cs₃₁ to Cs_{3(N+1)} exist between the unit cells V₁ to Vₙ and the other terminal of the capacitor C1.

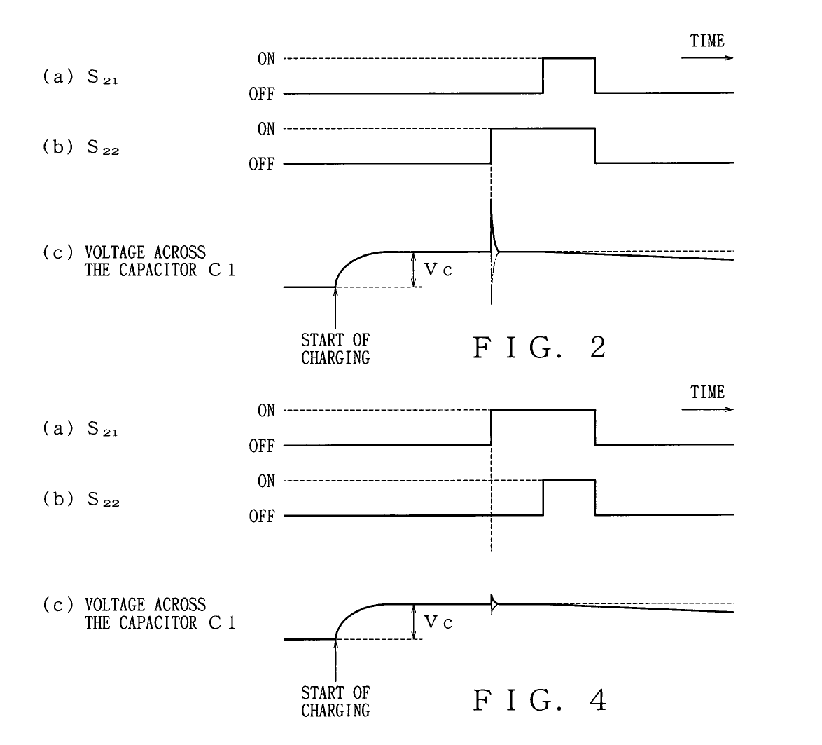

An operation of the voltage-measuring device 11 according to this invention will be explained below with reference to a timing chart of FIG. 2. Firstly, the capacitor C1 is charged by switching the switches S₁₁ and S₁₂, and the voltage across the capacitor C1 becomes Vc reflecting a voltage across a unit cell V₁. Secondly, the switches S₁₁ and S₁₂ are turned off to isolate the capacitor C1 from the battery pack P. Thirdly, the switch S₂₂ of the switches S₂₁ and S₂₂ are turned on.

Because the potentials of the unit cells V₁ to Vₙ connected to the stray capacitors Cs₁₁ to Cs_{1(N+1)}, Cs₂₁ to Cs_{2(N+1)}, Cs₃₁ to Cs_{3(N+1)} are different from those of the terminals of the voltmeter 10, when the switch S₂₂ is turned on, currents flow through the stray capacitors Cs₁₁ to Cs_{1(N+1)}, Cs₂₁ to Cs_{2(N+1)}, Cs₃₁ to Cs_{3(N+1)}.

As the currents flow, a switching noise is coupled to the voltage across the capacitor C1. Then, the potentials of the unit cells V₁ to Vₙ connected to the stray capacitors Cs₁₁ to Cs_{1(N+1)}, Cs₂₁ to Cs_{2(N+1)}, Cs₃₁ to Cs_{3(N+1)} are balanced with those of the terminals of the voltmeter 10, and the voltage across the capacitor C1 returns close to the Vc reflecting a voltage across a unit cell V₁.

Fourthly, the logic circuit turns the switch S₂₁ on. When the switch S₂₁ is turned on, the voltmeter 10 measures the voltage across the capacitor C1, and outputs a result of the measurement from an output terminal T. Because the potentials of the unit cells V₁ to Vₙ connected to the stray capacitors Cs₁₁ to Cs_{1(N+1)}, Cs₂₁ to Cs_{2(N+1)}, Cs₃₁ to Cs_{3(N+1)} are balanced with those of the terminals of the voltmeter 10 by previously turning the switch S₂₂ on, no current flows via the Cs₁₁ to Cs_{1(N+1)}, Cs₂₁ to Cs_{2(N+1)}, Cs₃₁ to Cs_{3(N+1)}.

Thus, no switching noise is coupled to the voltage measured by the voltmeter 10. Upon connecting to the voltmeter 10, the capacitor C1 is discharged gradually via an internal resistor of the voltmeter 10, and the voltage across the capacitor C1 is reduced from the voltage Vc gradually.

Therefore, by measuring the voltage across the capacitor C1 upon turning the switch S₂₁ on, the voltage Vc is measured accurately.

In a similar manner, the logic circuit sequentially turning on and off the Switches S₁₁ to S₁₍ₙ₊₁₎ to connect the unit cells V₂ to Vₙ to the capacitor C1 for charging the capacitor C1. At each time after the capacitor C1 is charged, the switches S₁₁ to S₁₍ₙ₊₁₎ are turned off, then the switch S₂₂ is turned on, and then the switch S₂₁ is turned on. The voltmeter 10 measures the voltage across the capacitor C1 upon each time when the switch S₂₁ is on, and outputs the result of the measurement from the output terminal T. Consequently, each of voltages across the unit cells V₁ to Vₙ of the battery pack P can be individually measured accurately.

### Second Embodiment

A second embodiment of a switch control apparatus, a witch control method, and a voltage-measuring device having the apparatus for controlling the switches will be explained with reference to Figures. In order to avoid repetitions, identical elements will be designated by identical reference numerals and only the differences existing in comparison with the first embodiment will be explained.

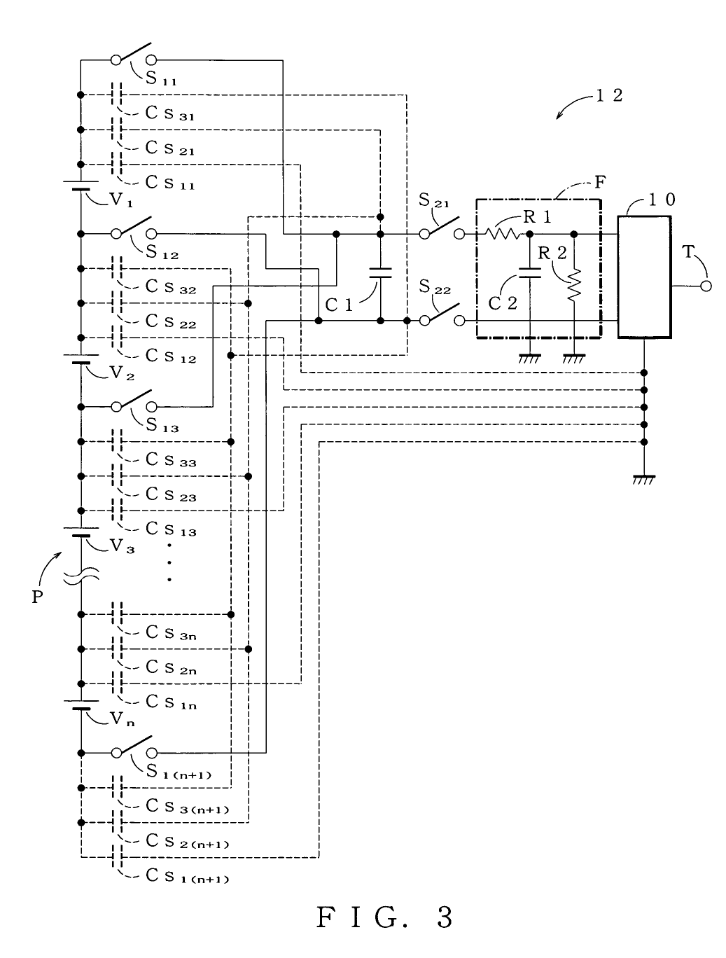

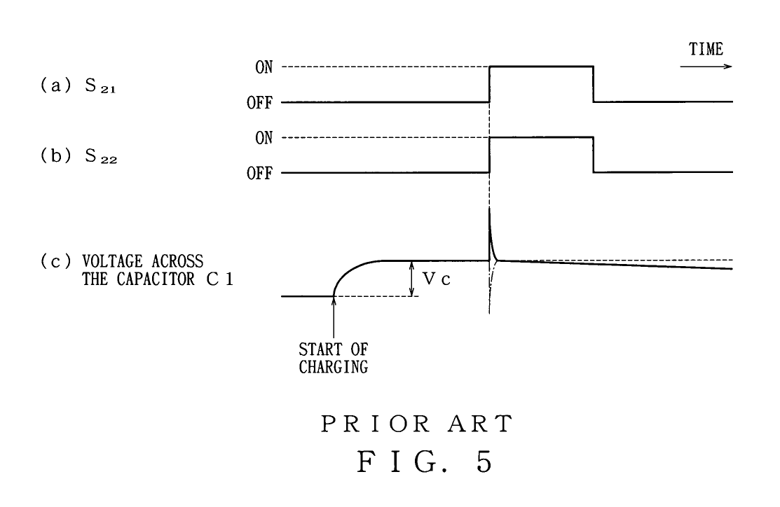

As shown in FIG. 3, a voltage-measuring device 12 further includes a low pass filter F provided between the switch S₂₁ to be firstly turned on in this second embodiment and the ground, in addition to the capacitor C1, and a plurality of the switches S₁₁ to S₁₍ₙ₊₁₎ for connecting corresponding unit cells V₁ to Vₙ connected in series to each other, to the capacitor C1 as described in the first embodiment. This low pass filter F includes resistors R1, R2, and a capacitor C2.

By providing the low pass filter F between the switch S₂₁ to be firstly turned on and the ground, as shown in FIG. 4, even when the switch S₂₁ is turned on, high frequency components of the switching noise are cut. Thus, each of voltages across the unit cells V₁ to Vₙ of the battery pack P can be individually measured accurately.

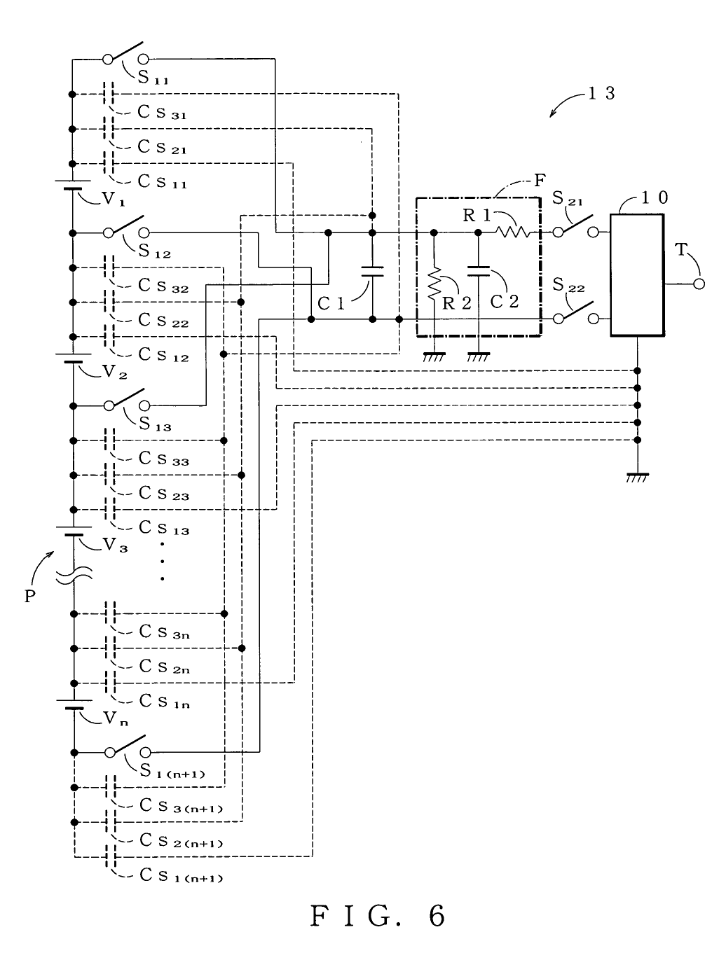

In addition, in the second embodiment as shown in FIG. 3, the low pass filter F is provided between the voltmeter 10 and the ground, however, as shown in FIG. 6, the low pass filter F may be provided between the terminal of the capacitor connected to the switch S₂₁ to be firstly turned on and a ground of the voltmeter.

Having now fully described the invention, it will be apparent to one of ordinary skill in the art that many changes and modifications can be made thereto without departing from the scope of the invention as set forth herein.

1. A switch control apparatus for checking voltages of a plurality of unit cells composing a battery pack, said switch control apparatus comprising:
a capacitor for being sequentially connected to the unit cells;
a voltmeter for measuring a voltage across the capacitor; and
two switches respectively provided between terminals of the capacitor and terminals of the voltmeter,
whereby either one of the two switches is firstly turned on, and then the other switch is secondly turned on.

2. A switch control method for controlling two switches respectively provided between each of terminals of a capacitor sequentially connected to a plurality of unit cells composing a battery pack for checking voltages of the unit cells, and a voltmeter for measuring a voltage across the capacitor, said method comprising the steps of:
firstly turning either one of the two switches on; and
secondly turning the other switch on.

3. A voltage-measuring device comprising:
a capacitor for being sequentially connected to a plurality of unit cells composing a battery pack;
a voltmeter for measuring a voltage across the capacitor;
two switches respectively provided between each of terminals of the capacitor and the voltmeter; and
a switch controller for controlling the two switches,
whereby any one of the two switches is firstly turned on, and then the other switch is secondly turned on,
whereby the voltmeter measures the voltage across the capacitor when the other switch is secondly turned on.

4. The voltage-measuring device as claimed in claim 3, further comprising a filter being provided between the terminal of the capacitor connected to the switch to be firstly turned on and a ground of the voltmeter.

5. The voltage-measuring device as claimed in claim 3, further comprising a filter being provided between the terminal of the voltmeter connected to the switch to be firstly turned on and a ground of the voltmeter.
